(19) United States
(12) Patent Application Publication
(10) Pub. No.: US 2009/0200905 A1
(43) Pub. Date: Aug. 13, 2009

(54) Panel Mounted Equipment, Cables and Conduits

(75) Inventors: Russell Peter GORE, Abingdon (GB); Richard Gowland, Bicester (GB)

Correspondence Address: CROWELL & MORING LLP;INTELLECTUAL PROPERTY GROUP, P.O. BOX 14300, WASHINGTON, DC, 20044-4300, US

(73) Assignee: Siemens Magnet Technology Ltd., Witney (GB)

(21) Appl. No.: 12/361,392

(22) Filed: Jan. 28, 2009

(30) Foreign Application Priority Data
Feb. 12, 2008 (GB) 0802560.3

(51) Int. Cl. H05K 5/02; H05K 5/03; B23P 11/00; H02K 15/10

(52) U.S. Cl. 312/400; 312/265.5; 29/445; 29/734

(57) ABSTRACT

In a method and apparatus for mounting and retention of ancillary equipment to cover panels of a magnetic field generator of a magnetic resonance imaging system having a cryogenic refrigerator and/or liquid cryogen housed within at least an outer vacuum container, ancillary equipment, cables and conduits are attached to the magnetic field generator, by integrating the electronic assemblies, cables and conduits into a set of modular covers which are connected to each other on installation. The covers may be mechanically mounted directly to the OVC, enabling them to be quickly fitted either in the factory or on the user's site.

The present invention relates to the mounting and retention of ancillary equipment to cover panels of a magnetic field generator of a magnetic resonance imaging (MRI) system.

The present invention may be used to house and retain ancillary equipment associated with magnetic field generators of MRI (magnetic resonance imaging) systems. The present invention will be described with particular reference to the mounting and retention of ancillary equipment, conduits and cables to cover panels of a magnetic field generator for an MRI system.

In a typical MRI system, a magnetic field is generated by a superconducting electromagnet. To keep the electromagnet at superconducting temperature, it is cooled by a cryogenic refrigerator and/or liquid cryogen, and is housed within at least an outer vacuum container (OVC) to reduce thermal influx from ambient temperature. Various measures are undertaken to reduce thermal influx to the electromagnet by convection, conduction or radiation. The OVC, the electromagnet and any other equipment retained within the OVC are referred to herein as “the magnetic field generator”. The OVC is typically encased within an outer cover (known as the “looks cover”) which is fitted to a metal framework provided around, or attached to, the OVC. In some instances, mounting brackets for the looks cover may be attached to the OVC, for example by welding or brazing. This cover, typically a shell of a thin resilient material such as glass-reinforced plastic GRP, provides a gap between the OVC and the inner surface of the shell which houses conduits, cables and some ancillary equipment such as electronic control and measurement circuitry. The ancillary equipment, cables and conduits may be attached to the metal framework discussed above, typically using a system of clamps and cable ties. The gap may be partially filled with a sound-deadening material to reduce the acoustic noise emitted by the magnetic field generator as a whole. An arrangement is typically provided to ventilate the gap by airflow around the OVC. The outer surface of the looks cover usually has an aesthetically attractive appearance, and determines the appearance of the system to users such as patients for imaging. The present invention is not concerned with the details of the electromagnet, nor its cooling or insulation arrangements. Indeed, the present invention is not directly concerned with the imaging system.

In addition to the electromagnet itself, much ancillary equipment must be provided, for example in the form of control and measurement electronics, electrical power supply, supply and return of cryogen gases and liquids, and much interconnecting electrical cabling. These need to be enclosed for both safety and aesthetic reasons. In earlier arrangements, an MRI system would be installed in a room provided or adapted for the purpose (known as the imaging suite) and much of the ancillary equipment would be separately housed within the imaging suite, connected to the magnetic field generator by a number of conduits and cables. Recently, it has become preferred to enclose much of the cables and conduits, and some of the ancillary equipment, within the gap between the OVC and the inside surface of the looks covers. While this has improved the appearance of the system, it has introduced difficulties, some of which will now be described.

The existing systems mount the ancillary equipment, conduits and cables to the OVC either in the factory or at the user site. Looks covers are then applied to the OVC to enclose the electronics, conduits and cables on the OVC. Performing these steps at an installation site, for example at a hospital, is time consuming for the installer and frustrating for the user, who has taken delivery of the MRI system but is unable to use it until these mounting and installation procedures are complete. This may result in significant downtime and disruption to existing facilities. For example, if replacing an MRI system with a newer version, the old MRI system will have to be decommissioned before the new one can be installed, and further downtime will result from the need for mounting the ancillary equipment, conduits and cables on to the new MRI system. During this downtime, the hospital may be left without a functional MRI system, which in turn may delay treatment of patients. A current alternative method, which involves fitting the ancillary equipment to the magnetic field generator in the factory reduces down-time at the user site, but represents the most time-consuming process in the assembly of the MRI system. Whichever method is chosen for the initial installation, upgrades to the system will require that the system be stripped of the obsolete items which could require removal of all covers and that any new item is attached using existing fittings on the OVC. When removing obsolete items, many non-obsolete cables and conduits may need to be removed from their mountings and re-fastened, adding to down-time. Similar considerations apply to repair of such systems.

Currently the various electronic assemblies required by the MRI system are attached as ancillary equipment to the OVC of the magnet, or a framework around or attached to the OVC, as separate entities with their own enclosures. Similarly, the various conduits and cables are routed around the outside of the OVC any typically attached to the framework every few millimeters by a nylon cable tie. The looks covers are then fitted around the system and over the ancillary equipment, cables and conduits by attachment to a metal framework attached to, or fixed around, the OVC.

The present invention addresses at least some of the difficulties encountered with known arrangements and provides an improved method and system for attaching ancillary equipment, cables and conduits to the magnetic field generator, by integrating the electronic assemblies, cables and conduits into a set of modular covers which are connected to each other on installation. These covers could be mechanically mounted directly to the OVC. This would enable them to be quickly fitted either in the factory or on the user's site, allowing for quick builds, installations, repairs and upgrades. This decrease of build time would allow decreased lead times on systems and reduced stock.

The present invention accordingly provides methods and apparatus as defined in the appended claims.

The above, and further, objects, characteristics and advantages of the present invention will be more apparent from consideration of the following detailed description of certain embodiments thereof, given by way of non-limiting example only, in conjunction with the following drawings, wherein:

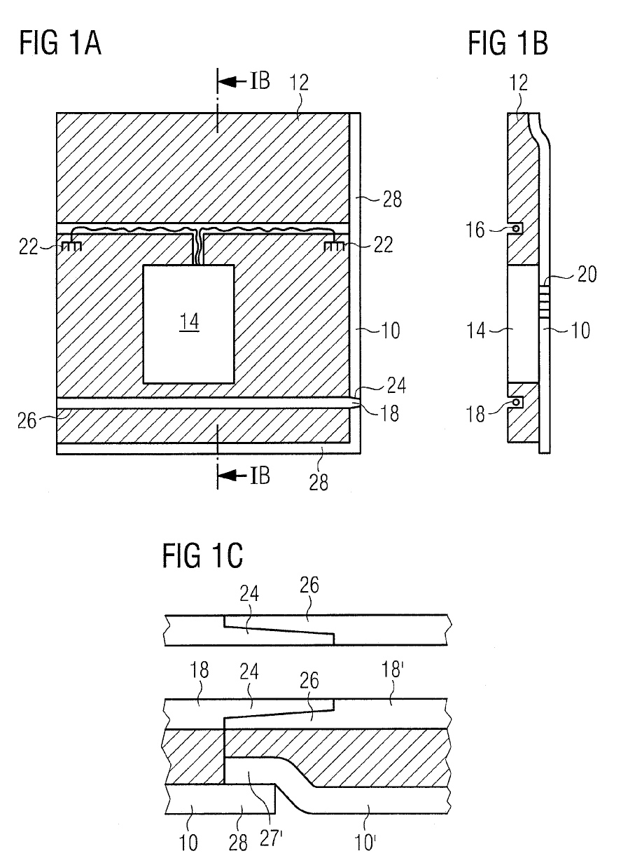

FIG. 1A shows a view of an interior surface of an integrated panel according to an embodiment of the present invention;

FIG. 1B shows a cross-section through the integrated panel of FIG. 1A along the line IB-IB;

FIG. 1C shows a cross-section through an arrangement providing connection of conduits in adjacent panels;

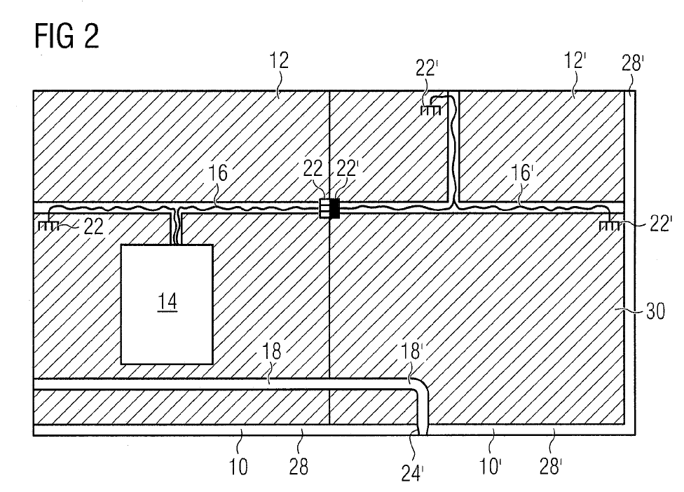

FIG. 2 shows an assembly of the integrated panel of FIG. 1A with an adjacent integrated panel of the present invention;

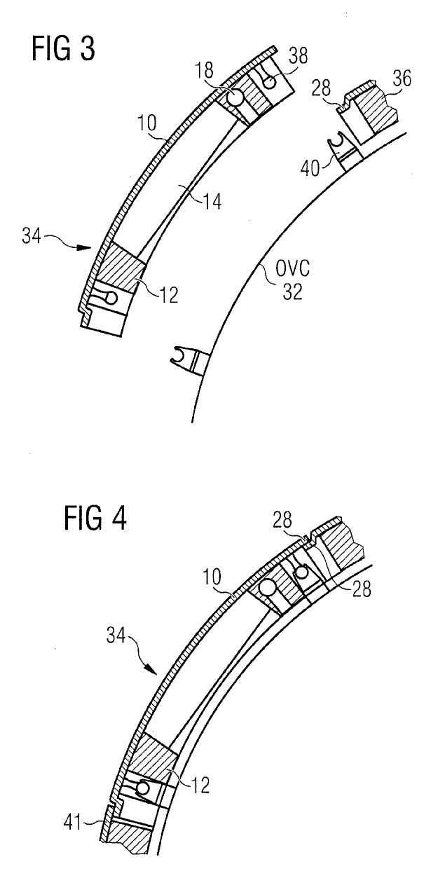

FIG. 3 shows a cross-section through a panel of an embodiment of the present invention as it is being brought into position on an OVC, adjacent to another integrated panel, according to an embodiment of the present invention;

FIG. 4 shows the arrangement of FIG. 3, wherein the panel is in position, mechanically attached to the OVC;

FIG. 5 shows a view, similar to that of FIG. 3, in which a panel of another embodiment of the present invention is being brought into position on an OVC, adjacent to another integrated panel, according to an embodiment of the present invention;

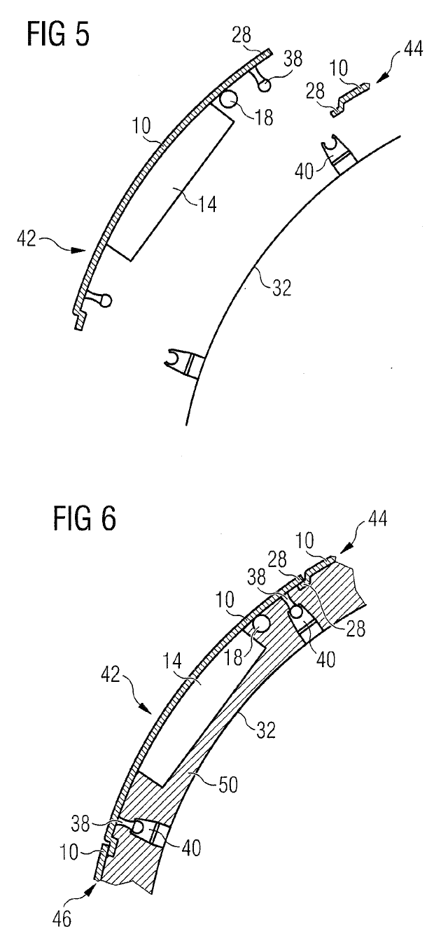

FIG. 6 shows the arrangement of FIG. 5, wherein the panel is in position, mechanically attached to the OVC, and insulation has been introduced into a gap between the panels and the OVC.

According to the present invention, at least some of the ancillary equipment, the cables and/or the conduits are integrated into the system's looks covers.

Each integrated cover comprises an outer looks cover skin providing an aesthetically pleasing outer appearance, and carries sections of ancillary equipment, cables and/or conduits, and is provided with connectors near its periphery so that, on installation, the connectors are connected to complementary connectors of an adjacent panel. In this way, cables and conduits which are required to extend over many panels are assembled as the panels of the looks cover are assembled together.

In one embodiment, acoustic foam is bonded to the inside surface of the looks covers, and conduits and cables are located in corresponding slots provided in the acoustic foam. These slots hold the conduits and cables in position more firmly than the known system of clamps and cable ties. Furthermore, in such embodiments, ancillary equipment such as electronic assemblies, typically each housed in a corresponding enclosure, may also be mounted in corresponding recesses in the foam.

In other embodiments, at least one piece of ancillary equipment is not fully enclosed, but is attached to the inner surface of the looks cover skin so as to use the internal surface of the looks cover skin to form part of their enclosure. In such an arrangement, ventilation holes may be provided through that part of the looks cover skin, to provide ventilation to the electronic assembly.

The covers could be mounted to the OVC using quick-fit fasteners such as snap-fitting fasteners or quarter-turn fasteners, either directly to the OVC or to anti-vibration mounts on the OVC. Such anti-vibration mounts would to reduce acoustic noise reaching the integrated covers, and may provide the added advantage of reducing mechanical vibration experienced by ancillary equipment, connectors, cables and conduits.

In such embodiments, the integrated covers are assembled onto the OVC as a collection of several individual panels. Each individual integrated panel comprises an outer looks cover skin, an inner layer of acoustic foam, and may comprise one or more of ancillary equipment such as an electronic assembly; conduit; cable. Each of the conduits and cables terminates in a connector in the vicinity of the perimeter of the panel. In such an embodiment, the panels are pre-fabricated, and when an MRI system is being assembled, the panels would be connected to one another as they are mounted onto the OVC of the magnetic field generator. Typically, attachment to the OVC would be by a removable fastener, such as a quarter-turn fastener, a snap-fit fastener, or set screws. Repair or upgrading may be achieved by simply replacing the affected panel(s). In case of a repair operation, the affected panel may be taken away for repair, to be re-installed or used on another system at a later date. This arrangement would allow repair of ancillary equipment, conduits and cables with an absolute minimum of down-time. It would also reduce the manufacturing time by decreasing the number of items that need to be fitted to the OVC and would reduce on-site installation time as mounting of the integrated cover panels would be relatively rapid.

An alternative approach would be to prefabricate only the outer looks cover skin, then, during factory assembly of the MRI system, mount the ancillary equipment, cables and conduits directly to the inner surface of the looks cover skin using temporary fixing methods e.g. adhesive tape. The panels of the looks cover skin, carrying the ancillary equipment, cables and conduits temporarily attached are then assembled onto the OVC. Finally, once all panels of the looks cover skin are secured in place, the remaining space between the magnet and the covers could be filled with insulation. The insulation should provide acoustic damping to reduce the mechanical vibrations which reach the outer surface of the looks cover skin.

In certain embodiments, the insulation is a loose, pellet-type such as expanded polystyrene beads. Similarly, sand or fine gravel may be used as a filler material, which is effective at sound insulation. Alternatively, the insulation may be provided by a chemically-generated foam such as polyurethane foam commonly used in the construction industry. FIG. 6 shows an example of such a structure. To provide for any necessity for installing ancillary equipment that needs to be fitted on-site, a recess may be formed in the foam using tooling forms during the foaming process which could be removed once the foam was formed and hardened. Arrangements may be made to allow airflow through the insulation, to provide cooling for ancillary equipment, cables and conduits located between the OVC and the looks cover skin.

The magnetic field generator in a typical MRI system is a cylindrical electromagnet, and the looks cover typically follows this general shape. Due to the functionality of the MRI system, and the mechanical properties of the OVC and the looks cover, more acoustic noise is generated at the annular end caps than at the cylindrical sides of the OVC. Accordingly, since the arrangement of the present invention reduces the space available for sound-deadening material between the OVC and the looks covers, it is preferable to employ the integrated covers arrangement of the present invention only for the covers for the cylindrical side surfaces of the OVC, with sound deadening material being present on the annular end pieces of the OVC.

As a typical MRI system will require many electrical cables to be run over the surface of the OVC, it is preferred that the present invention employs a loom structure, in that each panel has its cables assembled into a loom, preferably with a single electrical connector at each side of the periphery of the panel, such that a maximum of four electrical connectors need to be connected on installation of each panel. If required, it should be possible to limit the number of electrical connectors to three, one at each of up to three sides of each panel. Each panel is preferably approximately rectangular, with, in use, two sides parallel to the axis of the OVC and two sides each forming an arc of a circle centered on the axis of the OVC.

In embodiments of the present invention, the following types of ancillary equipment cables and conduits may be mounted on the inner surface of the looks cover skin: radio frequency (RF) electronic circuitry; signal processing circuitry; signal conditioning electronics; control electronics; signal and power cables; and conduits for cryogen and other fluids, provided that such equipment is not so heavy that it causes mechanical problems on installation, or deformation of the integrated covers. For this reason it may be preferred to not integrate power supply equipment, such as the gradient coil power supply of an MRI system, onto the panels of the looks cover.

Certain embodiments of the present invention will now be described in more detail. FIG. 1A shows a view of the inner surface of an integrated cover according to an embodiment of the present invention. FIG. 1B shows a cross-section of the cover of FIG. 1A, taken along the line IB-IB. A looks cover skin 10, typically a relatively thin GRP shell with an attractive outer surface, is just visible, but is largely covered in insulating material 12. Cavities are cut into the insulating material 12 to house ancillary equipment 14, a loom 16 of cables and a conduit 18. As can be seen more clearly in FIG. 1B, the cavities which house the loom 16 and the conduit 18 need not traverse the full thickness of the insulation 12. Preferably, the cavities have a width rather less than the width of the conduit or loom which they are intended to hold, such that the insulation may be deformed into resilient engagement with the associated conduit or loom on introduction thereof into the cavity. More preferably still, the cavity is tapered, such that the access to the cavity is narrower than the base of the cavity, whereby the conduit or loom may be more securely held within the cavity. The insulation 12 may be bonded to the looks cover skin 10 by an adhesive, by being formed in situ using a chemical foam which attaches to the looks cover skin, by barbed mechanical fasteners or by any other appropriate means. Preferably, the cavities in insulation 12 retain the looms 16 and conduits 18 so securely that further arrangements for retaining the looms and conduits are unnecessary. Such further arrangements for retaining the looms and conduits could of course be added if desired, or if required.

A cavity formed to accommodate ancillary equipment 14 traverses the full thickness of the insulation 12. Ventilation holes 20 may be provided through the looks cover skin 10, to provide ventilation for the ancillary equipment 14. The loom 16 and the conduit 18 extend only as far as the edges of the panel. Connectors are provided at the ends of the loom and the conduit on the panel. In the case of electrical looms, complementary plug and socket connectors 22 may be used, or any suitable equivalent. In the case of a conduit, a protrusion 24 of reduced external diameter may be provided, for insertion into an end portion 26 of increased internal diameter in an adjacent panel. FIG. 1C illustrates this feature in more detail. A taper may be provided on the protrusion 24 and the end portion 26, as illustrated, to assist assembly. Other arrangements may be made for connecting together the loom and conduit parts on adjoining panels. As also illustrated in FIG. 1C, peripheral parts 27′ of the looks cover skin 10 may be deformed so as to allow overlap between the looks cover skins of adjacent panels. Accordingly, an overlap part 28 of the looks cover skin 10 may be provided, extending beyond the insulation 12 on two adjacent sides of the panel.

FIG. 2 shows a view, similar to that of FIG. 1A, of the panel of FIG. 1A attached to a second panel 30, as during assembly of an MRI system. Features of the second panel carry reference numerals similar to those used for the first panel, but primed. As can be seen in the drawing, the insulation parts 12, 12′ are abutting, and the looks cover skin 10′ of the second panel 30 is overlapped by one of the overlap portions 28 of the looks cover skin 10 of the first panel. Second panel 30 carries a section of a conduit 18′ and a loom 16′ of cables. Loom 16′ is provided with plug and socket connectors 22′ in the vicinity of the panel edges. Conduit 18′ is provided with protrusion 24′ and end portion 26′ similar to those described above. At the interface between the first and second panels, plug and socket connectors 22, 22′ are connected, and the conduit is joined as shown in FIG. 1C. In a similar manner, a whole looks cover with integrated conduits, cables and ancillary equipment may be assembled around the OVC of an MRI system. As described above, the ancillary equipment, cables and conduits are preferably mounted only on the cylindrical surfaces of the OVC. Alternative arrangements may be made for looks covers on the annular end surfaces, or similar sector-shaped panels comprising a looks cover skin and insulating material may be provided and mounted to the OVC in a manner similar to that used for the panels carrying conduit and cable looms, according to the present invention.

FIG. 3 shows a cross-section, in a plane perpendicular to the axis of the OVC 32, of a panel 34 according to the present invention about to be mounted onto the OVC adjacent to panel 36 which is already in place. Panel 34 carries insulation 12, conduit 18 and a piece of ancillary equipment 14. Preferably, the conduit 18 is retained in position by the resilient interaction of the insulation 12. As illustrated, the ancillary equipment uses the inner surface of the looks cover skin 10 as one wall of its housing. In this example, a ball-and-socket snap-fitting mount is used, comprising ball parts 38 on the panel and complementary socket parts 40 on the OVC. As the panel 34 is brought into position, the conduit is connected to corresponding conduit part(s) on adjacent panel(s), for example using an arrangement illustrated in FIG. 1C, and the cable looms are connected, for example using plug and socket connectors 22, 22′ as described above. As the panel 34 is brought finally into position, ball-and-socket fasteners 38, 40 engage to retain the panel in position, conduit parts on adjacent panels fully engage and plug and socket connectors may come to rest in cut-outs provided for the purpose in the insulation material 12.

FIG. 4 shows the arrangement of FIG. 3 with panel 34 in position and a further panel 41 in place, overlapping panel 34. It may be observed that overlap portions 28 of the looks cover skin ensure a pleasing aesthetic appearance without unsightly gaps. Most of the space between the OVC and the looks cover skin is occupied by insulation 12, ancillary equipment 14, conduit 18 or looms (not visible). Connectors and mechanical mounts 38, 40 occupy a small proportion of this space.

FIGS. 5 and 6 show an alternative embodiment of the present invention. In this embodiment, the integrated panels are not themselves provided with insulation, but are assembled onto the OVC, with the resultant gap between the OVC and the looks cover skin 10 later being filled with an insulator. FIG. 5 shows a view, similar to that of FIG. 3, of a panel 42 according to an embodiment of the present invention about to be mounted onto the OVC 32 adjacent to panel 44 which is already in place. Panel 32 carries conduit 18 and a piece of ancillary equipment 14, but no insulation. The conduit 18 may be retained in position by adhesive tape, cable ties, adhesive or any suitable arrangement. As illustrated, the ancillary equipment may use the inner surface of the looks cover skin 10 as one wall of its housing, with the remaining surfaces of the housing being adhesively or otherwise attached to the inner surface of the looks cover skin. Alternatively, and preferably in this embodiment, the ancillary equipment 14 may be housed within a complete enclosure which is retained in position by adhesive tape, cable ties, adhesive or any suitable arrangement. As the panel 34 is brought into position, the conduit is connected to corresponding conduit part(s) on adjacent panel(s), for example using an arrangement as illustrated in FIG. 1C, and the cable looms are connected, for example using plug and socket connectors as described above. As the panel 34 is brought finally into position, ball-and socket fasteners 38, 40 engage to retain the panel in position, and conduit parts on adjacent panels fully engage. According to this embodiment, no insulation is present between the looks cover skin 10 and the OVC 32 at this stage. Ancillary equipment 14, conduit 18 and cable looms are held in position, possibly by temporary fixing means such as adhesive tape.

Once all panels are in position, the looks cover skin 10 forms a closed, or at least substantially closed, shell surrounding the OVC and spaced from it by a certain distance. The space between the looks cover shell and the OVC, which is not filled with ancillary equipment, cable looms or conduit, may then be filled with an insulating material. FIG. 6 shows the arrangement of FIG. 5 with panel 42 in position, between other panels 44, 46. The space between the looks cover skin 10 and the OVC 32 is filled with insulation 50. It may be observed that overlap portions 28 of the looks cover skin 10 overlap to provide a pleasing aesthetic appearance without unsightly gaps. Most of the space between the OVC and the looks cover skin is occupied by insulation 50, ancillary equipment 14, conduit 18 or looms (not visible). Connectors and mechanical mounts 38, 40 occupy a small proportion of this space.

As mentioned above, insulation 50 may be a loose, pellet-type such as expanded polystyrene beads. Similarly, sand or fine gravel may be used as insulation, and is effective at sound deadening. Alternatively, the insulation 50 may be provided by a chemically-generated foam such as polyurethane foam commonly used in the construction industry. To provide for installing ancillary devices later, a recess may be formed in the insulation using tooling forms during the foaming process which could be removed once the foam is hardened. Arrangements may be made to allow airflow through the insulation 50, to provide cooling for ancillary equipment, cables and conduits located between the OVC 32 and the looks cover skin.

The present invention accordingly provides a method of pre-assembling looks covers, ancillary equipment, cables and conduits of an MRI system into integrated cover panels, which may be rapidly assembled in a factory or at a user site. As a result, assembly times are reduced, the ancillary equipment, cables and conduits may be more securely retained than in the prior art, and repair and upgrading is simplified by allowing field engineers to simply replace a whole integrated panel, without having to remove and replace cables, conduits and ancillary equipment individually from mechanical mountings, as was the case in the prior art. The present invention also provides integrated panels comprising a looks cover skin, and one or more of ancillary equipment, cables and conduits affixed to an inner surface of the looks cover skin. Such integrated panels are installed and connected to surround a magnetic field generator of an MRI imaging system. As the panels are installed, connections are made between cables and conduits of adjoining panels, so forming complete cable runs and conduits as required to connect various parts of the MRI system.

It will be necessary to provide connection between the looms and conduits of the integrated panels of the invention, and external cables and conduits. Connectors for this purpose may be integrated into certain panels, or a manifold may be provided, comprising connectors for connection to external cables and conduits, and connectors for connection to integrated panels of the present invention.

The panel covers need not be aesthetic looks covers, but may be functional or protective covers.

1. A modular cover comprising a number of panels separately mounted on the outside of an equipment, each panel comprising an outer skins; said panels being arranged together to form the cover, at least one of the panels comprising at least one of the following attached to an inner surface of the outer skin:
cable;
conduit;
and wherein at least one connector is provided in the vicinity of an edge of the panel for connection of the cable and/or conduit to an adjacent panel, wherein the equipment comprises a magnetic field generator of a magnetic resonance imaging (MRI) system.

2. The modular cover according to claim 1, wherein at least two of the panels carry a cable, complementary connectors being provided in the vicinity of the edges of the panels such that the cables are connected together by the complementary connectors.

3. The modular cover according to claim 1, wherein at least two of the panels carry a conduit, complementary features being provided on the conduit in the vicinity of the edges of the panels such that the conduits are connected together by the complementary features.

4. The modular cover according to claim 1, wherein at least one of the panels further comprises ancillary equipment attached to an inner surface of the outer skin.

5. The modular cover according to claim 1, wherein at least one edge of the outer skin at least one panel is arranged to overlap the outer skin of an adjacent panel.

6. The modular cover according to claim 1, wherein at least one of the panels includes a layer of insulation on an inner surface of the outer skin, and the ancillary equipment, electrical cable and/or conduit, as appropriate, is retained within cavities in the layer of insulation.

7. The modular cover according to claim 1, wherein at least one of the panels is retained on the equipment by a number of snap-fit fasteners.

8. The modular cover according to claim 1, wherein at least one of the panels is retained on the equipment by a number of quarter-turn fasteners.

9. The modular cover according to claim 1, wherein the cable forms part of a cable loom.

10. The modular cover according to claim 1, wherein the magnetic field generator of a magnetic resonance imaging (MRI) system is cylindrical, and each panel is approximately rectangular, with, in use, two sides parallel to the axis of the magnetic field generator and two sides each forming an arc of a circle centered on the axis of the magnetic field generator.

11. Equipment comprising a magnetic field generator of a magnetic resonance imaging (MRI) system, provided with a modular cover according to claim 1, wherein a gap between an outer surface of the equipment and the inner surface of the outer skin of the panels is substantially filled with an insulating material; and the ancillary equipment, electrical cable and/or conduit, as appropriate, is retained within the insulating material.

12. The equipment according to claim 11, wherein the insulating material comprises a loose material.

13. The equipment according to claim 11, wherein the insulating material comprises a solid chemical foam.

14. A panel of a modular cover as defined in claim 1.

15. A method for installing a cover; and ancillary equipment, and/or cables and/or conduits onto a magnetic field generator of a magnetic resonance imaging (MRI) system, said method comprising the steps of:
providing a number of panels each comprising an outer skin, at least one of the panels comprising at least one of the following attached to an inner surface of the outer skin:
cables;
conduit;
wherein at least one connector is provided in the vicinity of an edge of the panel for connection of the cable and/or conduit to an adjacent panel; and
installing each panel separately onto the equipment such that the outer skin of the panels forms the cover.

16. The method according to claim 15, wherein at least two of the panels carry a cable, and the method further comprises connecting the cables together by complementary connectors in the vicinity of the edges of the panels to form a cable which extends over at least two panels.

17. The method according to claim 15, wherein at least two of the panels carry a conduit, and the method further comprises connecting the conduits together by complementary connectors in the vicinity of the edges of the panels, to form conduit which extends over at least two panels.

18. The method according to claim 15, comprising arranging the outer skin of at least one panel to overlap the outer skin of an adjacent panel.

19. The method according to claim 15, wherein installing at least one of the panels comprises mounting the panel on the equipment using a number of snap-fit fasteners.

20. The method according to claim 15, wherein installing at least one of the panels comprises mounting the panel on the equipment using a number of quarter-turn fasteners.

21. The method according to claim 15, wherein the method further comprises substantially filling a gap between an outer surface of the equipment and the inner surface of the outer skin of the panels with an insulating material; such that the ancillary equipment, electrical cable and/or conduit, as appropriate, is retained within the insulating material.

22. The method according to claim 21, wherein the insulating material comprises a loose material.

23. The method according to claim 21, wherein the insulating material comprises a solid chemical foam.
